(19) United States
(12) Patent Application Publication
(10) Pub. No.: US 2022/0300258 A1
(43) Pub. Date: Sep. 22, 2022

(54) DESIGN PROCESSING METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Masao YAMAZAKI, Kawasaki (JP); Tatsuaki WATANABE, Kamakura (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/410,184

(22) Filed: Aug. 24, 2021

(30) Foreign Application Priority Data
Mar. 18, 2021 (JP) 2021-045083

(51) Int. Cl. G06F 8/35; G06F 8/34; G06F 30/20; H04L 29/06

(52) U.S. Cl. CPC G06F 8/35; G06F 8/34; G06F 30/20; H04L 67/40

(57) ABSTRACT

According to one embodiment, a design processing method includes: in response to an initialization instruction from a model development environment, giving, by a block set representing a hardware IP, an instruction to each of operation mechanisms to execute an operation calculation, each of the operation mechanisms performing a hardware operation corresponding to a different one of blocks in the block set; acquiring, by the block set, an operation result from each of operation mechanisms; and, in response to an end instruction from the model development environment, giving an instruction to stop operation, the instruction being given by each of the blocks in the block set to a corresponding one of the operation mechanisms.

### CROSS-REFERENCE TO RELATED APPLICATIONS

This application is based upon and claims the benefit of priority from Japanese Patent Application No. 2021-045083, filed on Mar. 18, 2021, the entire contents of which are incorporated herein by reference.

### FIELD

An embodiment described herein relates generally to a design processing method.

### BACKGROUND

Techniques for creating a system architecture of hardware and software by a combination of a hardware module and a software module has been disclosed.

The model development environment generally provided realizes simulation and code generation, for general-purpose logic as an object. Therefore, for embedded system development, in order that each company's own hardware IP (for example, an Analog-to-Digital Converter (ADC) to be mounted on a Micro Controller Unit (MCU)) can be handled in the general model development environment, adjustment work is performed by manual input.

### BRIEF DESCRIPTION OF THE DRAWINGS

FIG. 1 is a diagram illustrating an example of an apparatus configuration of a design support apparatus according to an embodiment;

FIG. 2 is a diagram illustrating a basic configuration of a block set according to the embodiment;

FIG. 3 is a diagram illustrating an operation sequence of a control part at execution of simulation, according to the embodiment;

FIG. 4 is a diagram illustrating an example of a flow of code generation according to the embodiment;

FIG. 5 is a diagram illustrating an example of a configuration of a block set of an ADC according to the embodiment;

FIG. 6A is a diagram illustrating an example of a model created under a model development environment according to the embodiment;

FIG. 6B is a diagram illustrating an example of a model created under the model development environment according to the embodiment;

FIG. 7 is a diagram illustrating an example of a simulation result of a sample model according to the embodiment;

FIG. 8 is a diagram illustrating an example of an operation timing of respective parts at simulation according to the embodiment;

FIG. 9 is a diagram illustrating an example of a code generation result of a sample model according to the embodiment;

FIG. 10A is an explanatory diagram for using input/output for order determination according to a modification 1;

FIG. 10B is an explanatory diagram for using the input/output for order determination according to the modification 1;

FIG. 11A is a diagram illustrating an example of a sample model that represents a linkage function between an ADC and a PMD according to a modification 2;

FIG. 11B is a diagram illustrating an example of a sample model that represents a linkage function between an ADC and a PMD according to a modification 2;

FIG. 12A is a diagram illustrating an example of a simulation result of the model according to the modification 2;

FIG. 12B is a diagram illustrating an example of a simulation result of the model according to the modification 2;

FIG. 13 is a diagram illustrating an example of an operation sequence that indicates the linkage between the ADC, the PMD, and an HW operation simulation mechanism, according to the modification 2; and

FIG. 14 is a diagram illustrating an example of a detailed sequence until a conversion operation start instruction from the PMD to the ADC at 100 μs, on the assumption that the simulation result of FIG. 13 is obtained by performing a simulation at intervals of 50 μs, according to the modification 2.

### DETAILED DESCRIPTION

In general, according to one embodiment, a design processing method is disclosed, in which a model development environment performs design of a model by a block diagram and simulation of the model. The method includes: in response to an initialization instruction from the model development environment, setting individual initial values for operation mechanisms by a block set representing a hardware IP, each of the operation mechanisms performing a hardware operation corresponding to a different one of blocks in the block set; in response to a simulation execution instruction from the model development environment, giving, by each of the blocks in the block set, an instruction to a corresponding one of the operation mechanisms to execute an operation calculation and acquiring, by each of the blocks in the block set, an operation result from a corresponding one of the operation mechanisms; acquiring, by the model development environment from the block set, the operation results acquired by the blocks in the block set; and, in response to an end instruction from the model development environment, giving an instruction to stop operation, the instruction being given by each of the blocks in the block set to a corresponding one of the operation mechanisms.

An exemplary embodiment of a design processing method will be explained below in detail with reference to the accompanying drawings. The present invention is not limited to the following embodiment.

Embodiment

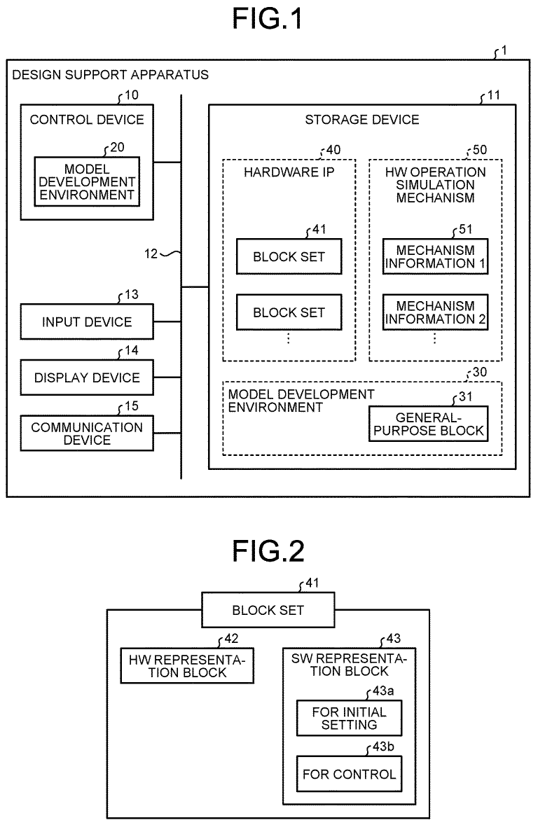

FIG. 1 is a diagram illustrating an example of the apparatus configuration of a design support apparatus according to an embodiment. The design support apparatus 1 illustrated in FIG. 1 is, for example, a computer that includes, as hardware components, a control device 10, a storage device 11, an input device 13, a display device 14, and a communication device 15. The respective devices are connected to each other over a bus 12. In this example, the control device 10 corresponds to “control means”, and the storage device 11 corresponds to “storage means”.

The control device 10 includes, for example, a Central Processing Unit (CPU) and executes a predetermined program stored in the storage device 11. The storage device 11 is a hard disk drive, Solid State Drive (SSD), or the like, and serves to store programs and data that are used for design support. The storage device 11 stores, as the predetermined program and data, a model development environment program 30, a general-purpose block (functional block or the like) 31 provided inside the model development environment, a block set 41 representing a hardware IP 40, such as an Analog-to-Digital Converter (ADC), mechanism information 51 of an HW operation simulation mechanism 50, and so on.

The model development environment refers to a model development environment for designing a model (that is, a model base) of a system. For example, MATLAB (R), Simulink (R), and so forth can be applied to the model development environment. In Simulink, a model is designed by a block diagram using a general-purpose block, and a code generated by MATLAB is executed on the model to perform a simulation. The block set 41 is a set of blocks for representing a hardware IP (for example, an ADC) for an embedded system or the like, and is prepared for each hardware IP.

The HW operation simulation mechanism 50 is an operation mechanism part that performs a simulation of an operation of the hardware IP (hardware such as an ADC). The HW operation simulation mechanism 50 includes mechanism information 51 corresponding to the hardware IP. In this embodiment, the HW operation simulation mechanism 50 is not used on the model development environment, but is used by a call from the block set 41. Note that the HW operation simulation mechanism 50 is a mechanism for simulation, so that it does not operate at code generation.

The input device 13 is, for example, a mouse and/or a keyboard that allow the user (a designer or the like) to perform various input operations on the control device 10. The input device 13 is used to perform, for example, selection of blocks, connection of lines between blocks, and/or various execution instructions.

The display device 14 is, for example, a liquid crystal display, and is used for showing screen information, such as a UI screen. For example, the display device 14 shows screen information, such as a block diagram.

The communication device 15 is a communication interface performing communication with an external device over a network. The communication device 15 can be used for updating data, or the like.

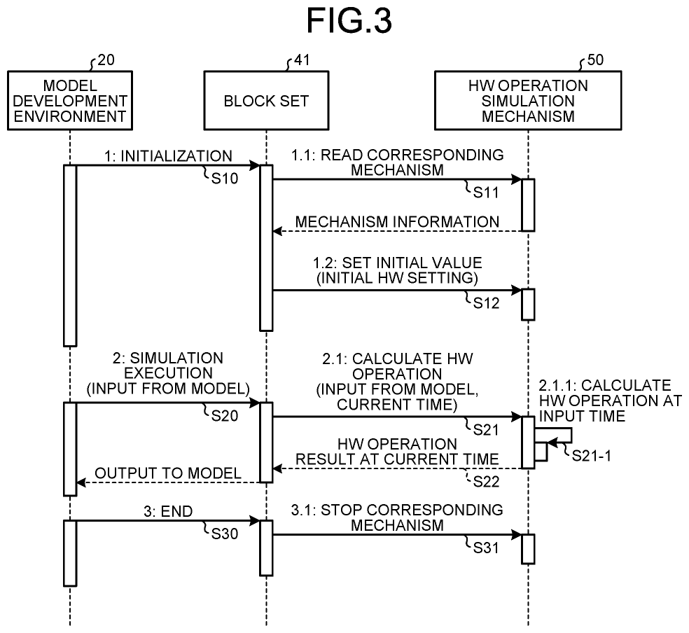

FIG. 2 is a diagram illustrating a basic configuration of each block set 41 illustrated in FIG. 1. As illustrated in FIG. 2, the block set 41 includes: an HW representation block 42 that represents the physical input/output of hardware, and an SW representation block 43 that represents the logical input/output from software to hardware.

Moreover, the SW representation block 43 includes: a block 43a for initial setting where the value of the hardware IP is fixed, and a block 43b for control where the value of the hardware IP changes during the operation.

The block set 41 is actually used as a component of a model on the model development environment. In simulation execution, the HW representation block 42 and the SW representation block 43 call and use the HW operation simulation mechanism 50 as an external mechanism. For example, the HW operation simulation mechanism 50 performs a simulation of an operation of the hardware IP depending on input from the HW representation block 42 and the SW representation block 43, and returns, to the HW representation block 42 and the SW representation block 43, operation results with respect to the input.

Design Processing Method

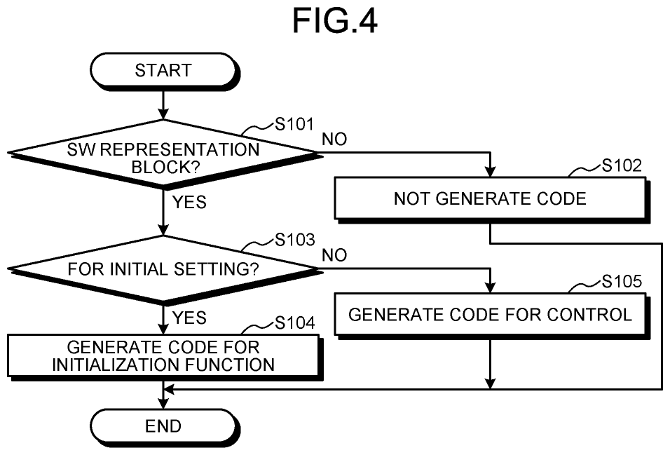

FIG. 3 is a diagram illustrating an operation sequence of a control part 20 at execution of simulation, in the design support apparatus 1. The control device 10 operates as a model development environment 20 by that, the CPU of the control device 10 illustrated in FIG. 1 executes the model development environment program 30. In the example illustrated in FIG. 3, the model development environment 20 gives, to the block set 41, three types of instructions: an initialization instruction (S10), a simulation execution instruction (S20), and an end instruction (S30). Hereinafter, an explanation will be given of a simulation operation based on the instructions from the model development environment 20.

First, in response to the initialization instruction given by the model development environment 20 (S10), each block in the block set 41 reads the corresponding mechanism information 51 of the HW operation simulation mechanism 50 (S11), and sets an initial value for the HW operation simulation mechanism 50 with respect to mechanism information needing an initial value (S12). The actions of S11 and S12 are performed for the linkage preparation and operation setting between each block in the block set 41 and the HW operation simulation mechanism 50.

Subsequently, in response to the simulation execution instruction given by the model development environment 20 (S20), each block in the block set 41 instructs HW operation calculation to the corresponding HW operation simulation mechanism 50 (S21), and acquires an HW operation result from the HW operation simulation mechanism 50 (S22).

For example, each block in the block set 41 gives to the HW operation simulation mechanism 50 the current time and the input value linked to the block, and obtains a calculation result of the HW operation from the HW operation simulation mechanism 50. At the input time (input current time), the HW operation simulation mechanism 50 calculates the HW operation (S21-1), and returns the result of the HW operation to the corresponding block (S22). In this way, the model development environment 20 acquires the result returned to each block in the block set 41, thereby obtaining a simulation result.

After the simulation is performed in this way, when the end instruction S30 is given from the model development environment 20, the block set 41 instructs the corresponding HW operation simulation mechanism to stop (S31).

In the design support apparatus 1, the behavior of the hardware IP is hidden in the HW operation simulation mechanism 50, and the block set 41 is treated as an interface between a model under the model development environment and the HW operation simulation mechanism 50. With this configuration, it becomes possible for the block set 41 to be linked with the HW operation simulation mechanism 50.

Code Generation

Next, an explanation will be given of code generation in the design support apparatus 1. When the code generation is performed, it is necessary to discriminate what type of code each block in the block set 41 generates. In the present embodiment, the code generation is performed under the following conditions.

First, as regards the HW representation block 42, the operation of the hardware IP does not have an influence at the code generation, so that the HW representation block 42 is treated as not needing the code generation. In other words, the HW representation block 42 represents the physical input/output as hardware, so that it cannot be seen from the viewpoint of software. Therefore, the HW representation block 42 is treated as non-existent in the code generation, thereby causing information on the physical input/output of the hardware not to appear in the code to be generated.

As regards the SW representation block 43, contents of the code to be generated are different between the initial setting block 43a and the control block 43b. For example, a code to be called only once at initialization is generated for the initial setting block 43a, whereas a code to be called a plurality of times during the operation is generated for the control block 43b. In this way, the codes to be generated by the initial setting block 43a and by the control block 43b are clearly discriminated. With this configuration, a plurality of control blocks 43b are prevented from generating duplicative initial setting codes, or generating inconsistent initial setting codes. In this design support apparatus 1, the code generation is performed under these conditions by the following flow.

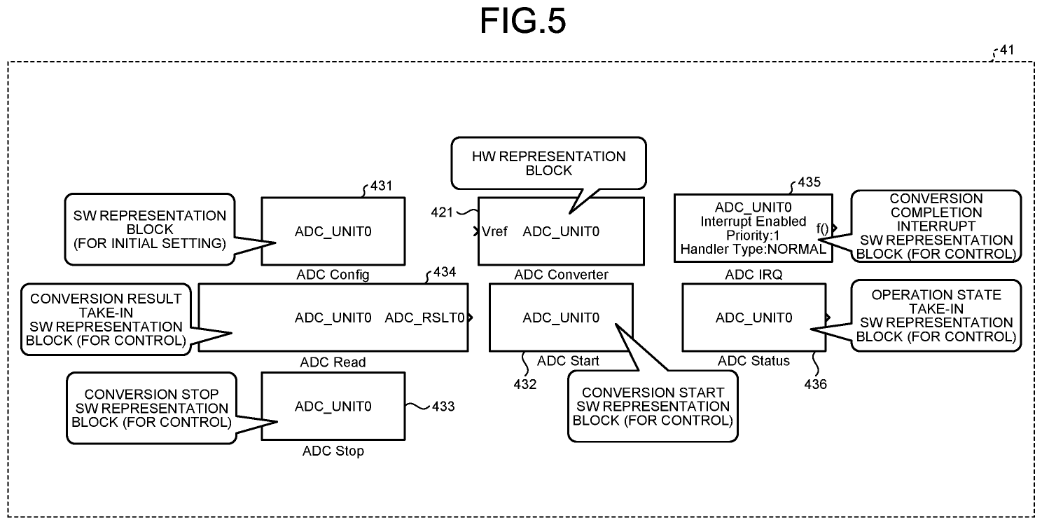

FIG. 4 is a diagram illustrating an example of the flow of code generation. The control part 20 of this design support apparatus 1 also functions as “generation means”. Specifically, the control part 20 specifies one by one each block configured in a model under the model development environment, and repeats the flow illustrated in FIG. 4 to perform the code generation for each block. First, the control part 20 determines whether the specified block is an SW representation block 43 or not (S101). In response to determining that the specified block is not an SW representation block 43 (S101: No), the control part 20 does not perform the code generation for this block (S102).

On the other hand, in response to determining that the specified block is an SW representation block 43 (S101: Yes), the control part 20 determines whether this block is an initial setting block 43a or not (S103).

The SW representation block 43 is either initial setting block 43a or control block 43b. Therefore, in response to determining that the block is an initial setting block 43a (S103: Yes), the control part 20 generates an initial setting code (code for initialization function) (S104). In response to determining that this block is not an initial setting block 43a (S103: No), the control part 20 generates a control code (S105). The generated code can be expanded and implemented in an embedded system (such as an MPU or a DSP).

As described above, the control part 20 also functions as a code generation part, and performs the necessary code generation for each block configured in a model under the model development environment.

Next, a specific example of the hardware IP provided in the design support apparatus 1 will be described. Here, as an example, an explanation will be given of a case where the hardware IP of an ADC is provided as a block set (which will be referred to as “ADC block set”, hereinafter) 41.

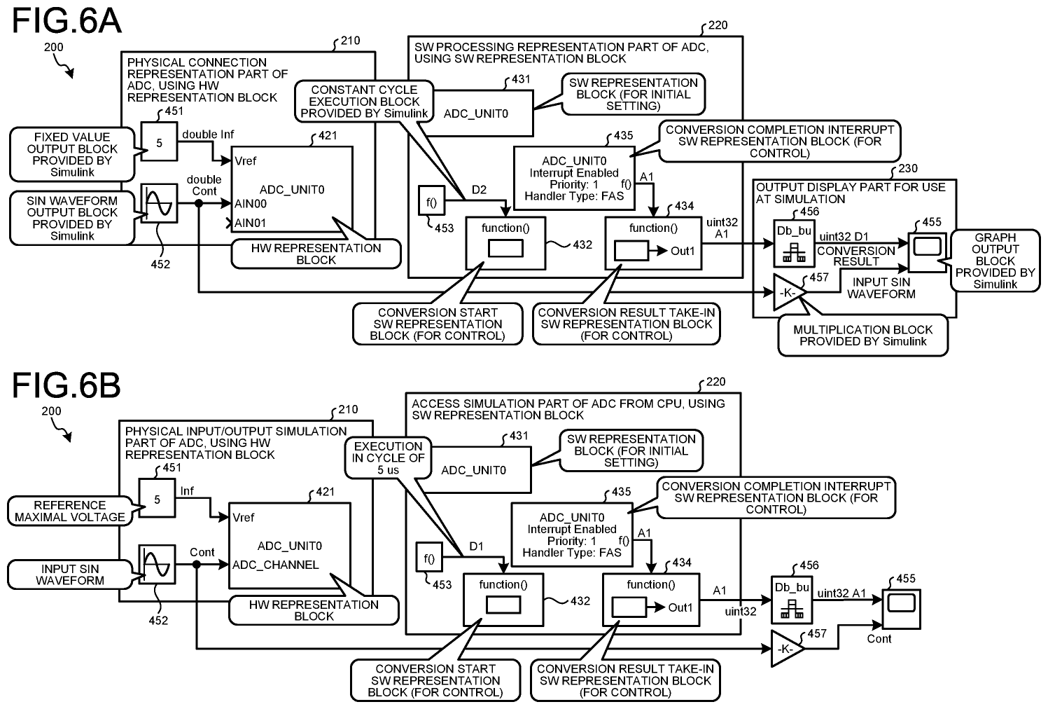

FIG. 5 is a diagram illustrating an example of the configuration of an ADC block set 41. The ADC block set 41 illustrated in FIG. 5 represents the hardware IP of an ADC by a single HW representation block 421 and six SW representation blocks 431 to 436. For each block, the type of the block is indicated by a balloon. Here, this example is composed of one HW representation block 421 and six SW representation blocks 431 to 436, but the number of representation blocks in each group may be appropriately determined in accordance with the type or the like of the hardware IP.

In the case of the HW representation block 421, consideration is given to physical input/output as hardware of the ADC. In the case of the ADC used in this example, there are only inputs to the ADC, such as AD conversion target and reference voltage. Therefore, the HW representation block 421 is indicated by a single block that represents input only.

For the SW representation blocks 431 to 436, consideration is given to an Application Programming Interface (API) in a case where the ADC is used from software. In the case of the ADC used in this example, the conceivable control includes ADC initial setting, conversion start and stop, conversion result acquire, conversion completion interrupt, operation state acquire, and so on. Therefore, the SW representation blocks 431 to 436 are indicated by six blocks that are thought necessary to represent the respective operations on the model. In this example, the SW representation block 431 corresponds to an initial setting block, the SW representation block 432 corresponds to a control block for conversion start, the SW representation block 433 corresponds to a control block for conversion stop, the SW representation block 434 corresponds to a control block for conversion result acquire, the SW representation block 435 corresponds to a control block for conversion completion interrupt, and the SW representation block 436 corresponds to a control block for operation state acquire.

When the SW representation blocks 431 to 436 are differentiated by the API level, the range of a code that each of the SW representation blocks 431 to 436 should output is clarified. Thus, it becomes possible to avoid inconsistencies between the SW representation blocks during execution.

Next, with reference to an example of a model created by using the block set 41 illustrated in FIG. 5 under the model development environment, an explanation will be given of the role of each part.

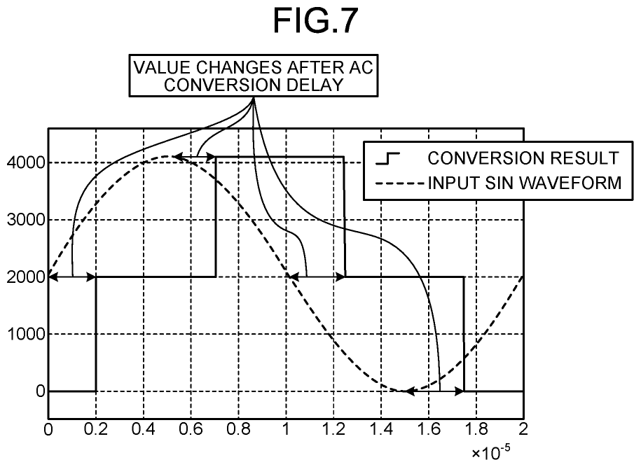

FIGS. 6A and 6B are diagrams illustrating an example of a model (sample model) created under the model development environment. The sample model 200 illustrated in FIGS. 6A and 6B is a model that has been created by a designer by manipulating a UI screen displayed on the display device 14 with the input device 13, thereby appropriately using a general-purpose block (functional block) provided by the model development environment and the ADC block set 41. As an example, the illustrated model represents actions that software starts AD conversion in the ADC every 5 μs and acquires a result by AD conversion completion interrupt. For each block, the type of the block is indicated by a balloon.

The blocks of the sample model 200 of FIG. 6A can be grouped into a physical connection representation part 210 of the ADC, an SW processing representation part 220 of the ADC, and an output display part 230 for use at simulation.

The physical connection representation part 210 of the ADC represents the physical connection relationship by combining functional blocks 451 and 452 with the HW representation block 421. For example, it is assumed that an SIN waveform is input to the ADC to represent a physical connection relationship that the SIN waveform is connected to the ADC. In this case, as illustrated in FIG. 6A, with respect to the HW representation block 421, a reference voltage of 5 V is input by a fixed value output block 451 being the functional block 451, and an SIN waveform with an amplitude of 2.5 V as a conversion target is connected by an SIN waveform output block 452 being the functional block 452.

As illustrated in FIG. 6A, for representing a targeted software operation, the SW processing representation part 220 of the ADC is provided by combining four SW representation blocks 432, 434, 435, and 431, which correspond to conversion start, conversion result acquire, conversion completion interrupt occurrence, and initial setting, respectively. Specifically, in order to represent the conversion result acquire performed with the conversion completion interrupt, the SW representation block 435 for the conversion completion interrupt is connected to the SW representation block 434 for the conversion result acquire. The SW representation block 431 for the initial setting is placed as it is because this block is for initial setting. Moreover, in order to represent the conversion start every 5 μs as in this example, a constant cycle execution block 453 set to a cycle of 5 μs, which is a functional block, is connected to the SW representation block 432 for the conversion start.

The output display part 230 for simulation is provided by combining functional blocks for outputting a simulation result on a graph. In this example, a graph output block 455 is used. Before the graph output block 455 is connected, an SIN waveform output block 456 changes a value by a multiplication block 457 to match the range of the conversion result acquire output. FIG. 6B illustrates the states of the respective parts at the simulation, as a reference.

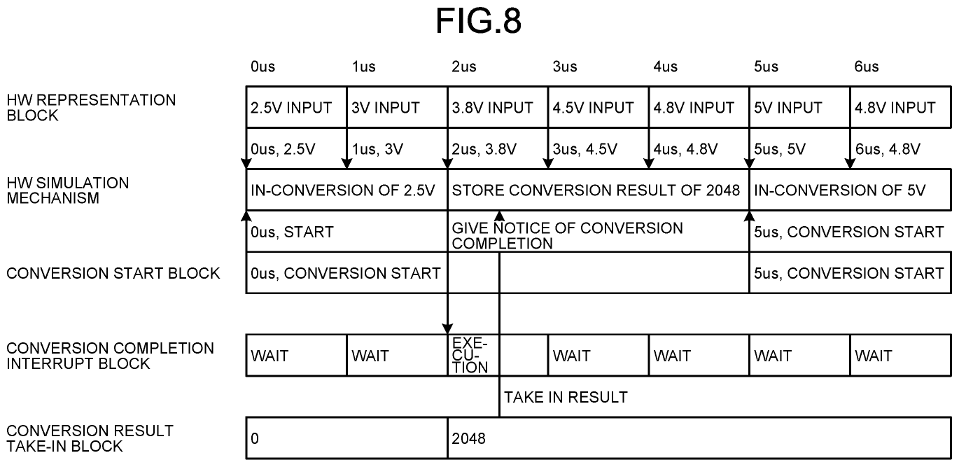

FIG. 7 is a diagram illustrating an example of a simulation result of a sample model. In FIG. 7, a result of an operation simulation of an example ADC is illustrated. From this simulation result, it can be seen that the SIN waveform input to the HW representation block 421 is converted in a cycle of 5 μs with a delay of 2 μs necessary for AD conversion in the target ADC. In this way, according to this apparatus, it is possible to correctly simulate the hardware IP of the ADC.

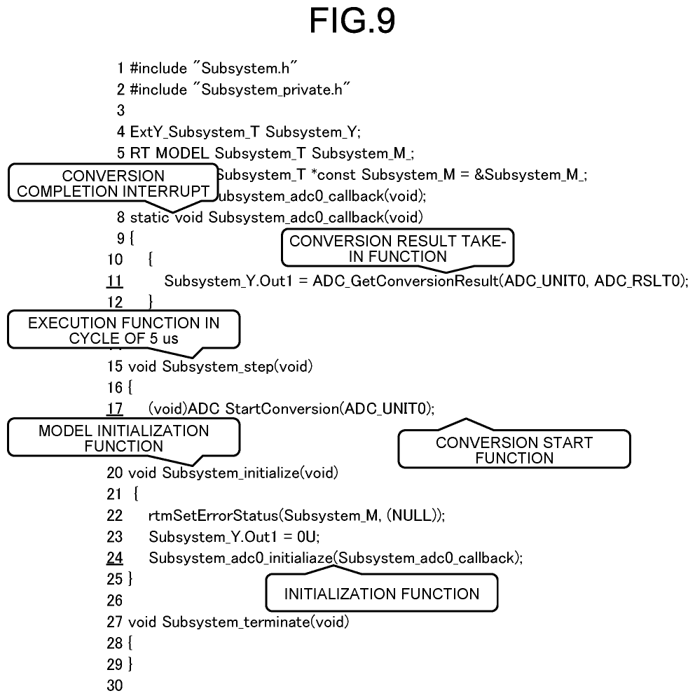

FIG. 8 is a diagram illustrating an example of the operation timing of respective parts illustrated in FIG. 6A at the simulation. In FIG. 8, the illustrated operation timing is used for the case that the model development environment executes the simulation every 1 μs.

The HW representation block 421 gives an input value, which is to be sent to the ADC at each time, to the HW operation simulation mechanism 50 every 1 μs. The HW operation simulation mechanism 50 selects an input value of 2.5 V given by the HW representation block 421 at 0 μs given by the conversion start block 432, and becomes an in-conversion state until 2 μs. When a time of 2 μs is given by the HW representation block 421, the HW operation simulation mechanism 50 judges that this is the conversion completion timing, and instructs execution to the conversion completion interrupt block 435. The conversion result acquire block 434 connected to the conversion completion interrupt block 435 requests result acquire at 2 μs to the HW operation simulation mechanism 50. The HW operation simulation mechanism 50 returns “2048”, which is a conversion result at 2 μs. 5Thereafter, the HW operation simulation mechanism 50 selects an input value of 5 V given by the HW representation block 421 at 5 μs given by the conversion start block 432, and becomes an in-conversion state again until 7 μs. In this way, the HW operation simulation mechanism 50 is given the time for each block, and the HW operation simulation mechanism 50 performs appropriate behavior for the HW operation at this time, thereby realizing the operation simulation of the hardware IP on the simulation.

For the code generation, when a code generation instruction is given from the model development environment, each SW representation block determines a code to be output in accordance with the rule set for each block, and outputs the code. For example, the four SW representation blocks 431, 432, 434, and 435 used in the sample model 200 of the example have the following rules.

Rules

The Conversion Start Block: Output an AD Conversion Start Function.

The conversion result acquire block: Output a conversion result acquire function as an input to the connection destination block.

The conversion completion interrupt block: Output an interrupt function with respect to processing of a code generated by the connection destination block.

The initial setting block: Output, when the conversion completion interrupt block is present, an initialization function with the interrupt function handler thereof as an argument, or Output, when the conversion completion interrupt block is absent, an initialization function with NULL as an argument.

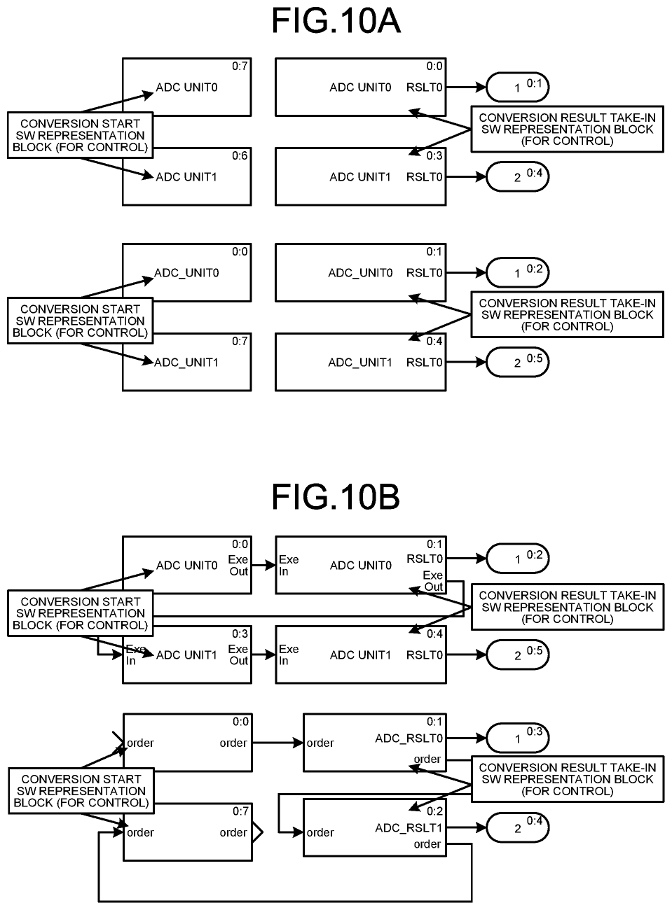

FIG. 9 is a diagram illustrating an example of a code generation result of the sample model 200. In the illustrated code generation result, it can be seen that control C codes are correctly generated from the four SW representation blocks 431, 432, 434, 435 in accordance with the rules described above. From the conversion start block 432, an AD conversion start function ADC_StartConversion is output to a 5 μs execution function Subsystem step. From the conversion result acquire block 434, a conversion result acquire function ADC_GetConversionResult is output as an input of Subsystem_Y.Out1. From the conversion completion interrupt block 435, an interrupt function Subsystem_ADCO_callback is output with respect to processing of the conversion result acquire function that is the connection destination. From the initial setting block 431, an initialization function Subsystem_ADCO_initialize is output to a model initialization function Subsystem_ initialize, with an interrupt function handler Subsystem_ADCO_callback as an argument.

From the result described above, it can be seen that the design support apparatus 1 is capable of implementing simulation and code generation for the hardware IP from the same model.

According to the present embodiment, the design support apparatus for the model development environment is provided with the block set as a hardware IP, which includes the HW representation block representing the physical input/output of hardware and the SW representation block representing the logical input/output from software to hardware. In the design support apparatus, in response to an initialization instruction from the model development environment, a block set representing the hardware IP sets individual initial values for HW operation simulation mechanisms, each corresponding to a different one of blocks in the block set. In response to a simulation execution instruction from the model development environment, each block instructs operation calculation to the corresponding HW operation simulation mechanism, and acquires an operation result. The model development environment acquires the operation results acquired by the blocks, from the block set that the blocks belong to. In response to an end instruction from the model development environment, each block instructs the corresponding HW operation simulation mechanism to stop. As a result, even with a non-general-purpose hardware IP, such as each company's own hardware IP, the operation result of the model simulation is obtained while the HW operation simulation mechanism is called not by the model development environment but by the block set. Therefore, it is possible to attain an advantage in that even a non-general-purpose hardware IP can be handled in the model development environment.

Moreover, the model development environment determines whether each block in the block set is an SW representation block or an HW representation block at the code generation of the hardware IP, and the code generation is performed when the block is an SW representation block. As a result, it is possible to attain an advantage in that this design support apparatus allows the simulation and the code generation for the hardware IP to be performed by the same model.

Furthermore, the block set includes the HW representation block and the SW representation block, so that it is possible to attain an advantage in that the efforts to handle a non-general-purpose hardware IP in the general model development environment are greatly reduced.

Modification 1

One of modifications of the embodiment will be described. In the present modification, input/output for order determination can be used in addition to the logical input/output. For explaining advantage of the input/output for order determination, an explanation will be given by comparison with a case where the input/output for order determination is not used.

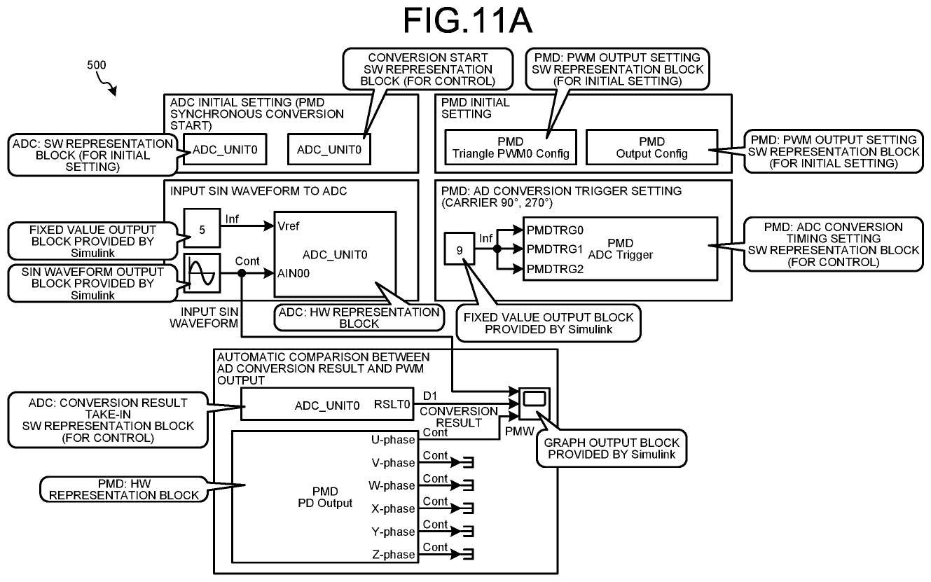

FIGS. 10A and 10B are explanatory diagrams for using input/output for order determination according to a modification 1. Specifically, FIG. 10A illustrates an example of a sample model in a case where the input/output for order determination is not used, and FIG. 10B illustrates an example of a sample model in a case where the input/output for order determination is used. The numbers (x:y) on the right shoulder in FIGS. 10A and 10B indicate the execution priority. The execution is performed in ascending order from the smallest number.

In the model development environment, the execution order is determined based on the input/output connection relationship. In the model of FIG. 10A, which does not use the input/output for order determination, the SW representation blocks are not connected to each other. Thus, the execution order depends on the internal processing of the model development environment, and becomes indeterminate. In the example illustrated in FIG. 10A, the conversion result acquire executes ADC UNIT1 after execution of ADC UNIT0, whereas the conversion start executes ADC UNIT0 after execution of ADC UNIT1. This order is likely to be an unintended order, and it is impossible to read, from the arrangement of the sample model, that this order is to come.

The reason why there is an SW representation block that does not have a connection relationship like this resides in that, the SW representation block represents the input/output from software to hardware, and an SW representation block performing input/output of a fixed value to the HW does not include input/output. For example, in the case of an ADC, the conversion start block is a block that instructs conversion start to the ADC. When consideration is given as an API used with actual software codes, since this API does not includes either of an argument and a return value, the corresponding conversion start block also does not include either of input and output. The conversion result acquire block is a block that acquires a conversion result from the ADC. When consideration is given as an API, since this API includes a return value but does not include an argument, the conversion result acquire block includes only output and does not include input. As a result, in this model, the conversion start block and the conversion result acquire block are not connected to each other, and the block execution order becomes indeterminate. Some control can be performed by assigning a priority to each block, but the readability of the model cannot be improved.

The above problem can be solved by adding the input/output for order determination in a way that does not affect the simulation operation and the code generation. When the input/output for order determination is added to the SW representation block, each conversion start block and each conversion result acquire block can be mutually connected, as illustrated in FIG. 10B. Consequently, the order of result acquire after conversion start and the order of conversion start after result acquire become determinate, and the readability of the model can also be improved. Further, in order not to affect the simulation operation and the code generation, the input/output for order determination is implemented as follows. It is set that the input side discards values and the output side can output arbitrary values, at the simulation, by which it is made possible to select values that do not affect the results of other processing, at the simulation. It is also set that both of the input and output sides do not generate codes at the code generation, by which it is made possible not to affect the code generation result. Consequently, the execution order of the model becomes determinate without affecting the simulation and the code generation, and thus the readability thereof can be improved.

Modification 2

Another modification will be described. The present modification enables a linkage operation between different hardware IPs on the model development environment. An HW operation simulation mechanism is linked with an HW operation simulation mechanism of another hardware IP, presenting a hardware IP that has a linkage function between hardware IPs. An explanation will be given of a hardware IP that links an ADC and a PMD with each other. As a hardware linkage function between an ADC and a PMD, there is a function that automatically starts a conversion operation of the ADC with timing according to an output signal output by the PMD.

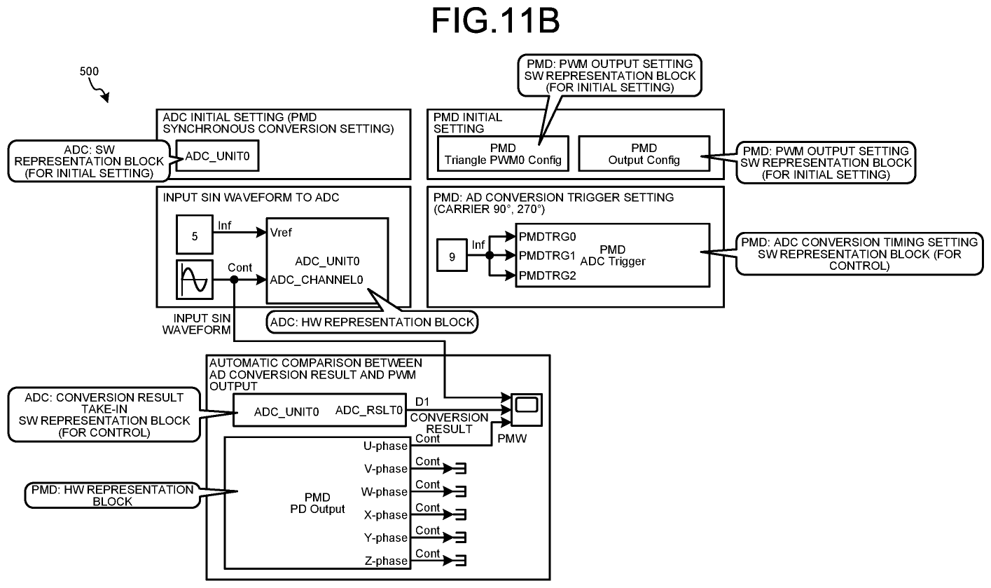

FIG. 11A (FIG. 11B) is a diagram illustrating an example of a sample model that represents a linkage function between an ADC and a PMD according to a modification 2. The sample model 500 represents a hardware linkage operation, in which the PMD outputs a signal whose output is switched every 100 μs and the conversion operation of the ADC is automatically started with the timing when the output is switched. For each block, the type of the block is indicated by a balloon.

The model 500 uses blocks for performing ADC initial setting (PMD synchronous conversion start) and for inputting an SIN waveform to the ADC, and blocks for performing PMD initial setting, for performing AD conversion trigger setting in the PMD, and for automatically comparing the AD conversion result with the PWM output.

The ADC initial setting (PMD synchronous conversion start) corresponds to an SW representation block represented by an SW representation block (for initial setting) of the ADC and an SW representation block (for control) of the conversion start. The block for inputting an SIN waveform to the ADC corresponds to an HW block represented by a general-purpose fixed value output block, a Sin waveform output block, and an HW representation block of the ADC. The PMD initial setting corresponds to an SW representation block that represents PWM output setting of the PMD. The AD conversion trigger setting in the PMD corresponds to an SW representation block represented by a fixed value output block of a general-purpose block and a block of ADC conversion timing setting in the PMD. The block for automatically comparing the AD conversion result with the PWM output corresponds to a block represented by an SW representation block that acquires the conversion result of the ADC and an HW representation block of the PMD.

The reference voltage and the SIN waveform are connected to the HW representation block of the ADC illustrated in FIG. 11A (FIG. 11B) by using a general-purpose block as in the example illustrated in the embodiment. In the modification 2, the conversion start of the ADC is executed only once for the purpose of activating the ADC at the simulation start. However, the AD conversion timing of the PMD can be set by the AD conversion trigger setting of the PMD, so that the ADC conversion operation is automatically started, by the hardware linkage function between the ADC and the PMD, with the timing when the PMD output is switched.

In other words, although the conversion start block of the ADC performs execution only once for the purpose of activating the ADC at the simulation start, as the hardware linkage function between the ADC and the PMD is realized, it is possible to simulate the operation that the ADC conversion operation is automatically started with the timing when the PMD output is switched.

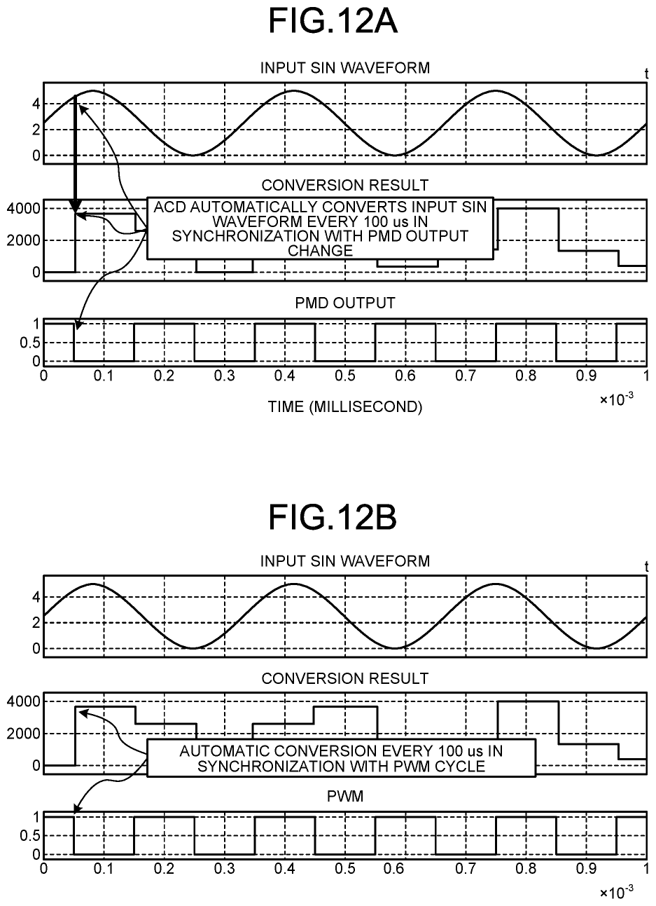

FIG. 12A (FIG. 12B) is a diagram illustrating an example of a simulation result of the model illustrated in FIG. 11A (FIG. 11B). It can be seen that the conversion start block is executed only once at the simulation start, but the conversion operation of the ADC is performed with the timing when the PMD output is switched, and the value of the conversion result acquire block is changed.

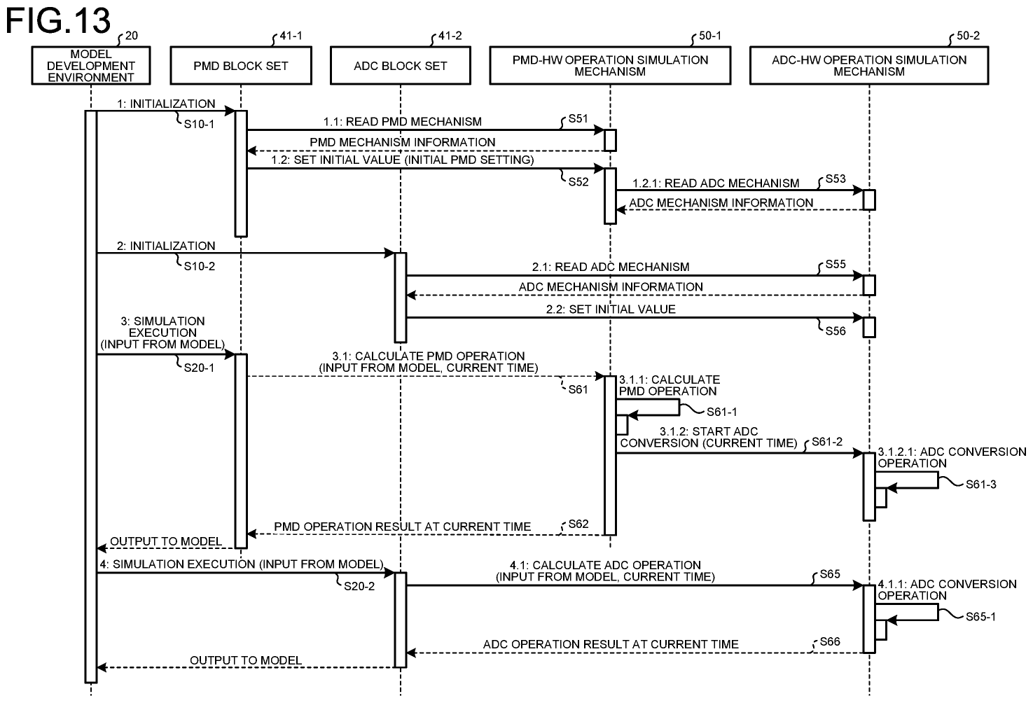

FIG. 13 is a diagram illustrating an example of an operation sequence that indicates the linkage between the ADC, the PMD, and the HW operation simulation mechanism. FIG. 13 illustrates an operation in the operation sequence of FIG. 3, on the assumption that the block set 41 includes a PMD block set 41-1 and an ADC block set 41-2, and the HW operation simulation mechanism 50 includes HW operation simulation mechanisms 50-1 and 50-2 of the PMD and the ADC, respectively.

In the example illustrated in FIG. 13, the model development environment 20 gives, to the PMD block set 41-1 and the ADC block set 41-2, three types of instructions: an initialization instruction (S10); a simulation execution instruction (S20); and an end instruction (S30). The example illustrated in FIG. 13 illustrates actions that an initialization instruction (S10-1) and a simulation execution instruction (S20-1) are given to the PMD block set 41-1, and an initialization instruction (S10-2) and a simulation execution instruction (S20-2) are given to the ADC block set 41-2. Note that the illustration of each end instruction (S30) is omitted in FIG. 13 because this instruction only stops the corresponding HW operation simulation mechanism.

In FIG. 13, the model development environment 20 first instructs initialization to the PMD block set 41-1 (S10-1). In response to the initialization instruction, each block in the PMD block set 41-1 reads the corresponding PMD mechanism information of the HW operation simulation mechanism 50-1 of the PMD (S51), and sets an initial value for the HW operation simulation mechanism 50-1 of the PMD with respect to mechanism information needing an initial value (S52). Subsequently, the HW operation simulation mechanism 50-1 of the PMD reads the ADC mechanism information of the HW operation simulation mechanism 50-2 of the ADC (S53).

Subsequently, the model development environment 20 instructs initialization to the ADC block set 41-2 (S10-2). In response to the initialization instruction, each block in the ADC block set 41-2 reads the corresponding ADC mechanism information of the HW operation simulation mechanism 50-2 of the ADC (S55), and sets an initial value for the HW operation simulation mechanism 50-2 of the ADC with respect to mechanism information needing an initial value (S56).

Subsequently, the model development environment 20 instructs simulation execution to the PMD block set 41-1 (S20-1). In response to the simulation execution instruction, each block in the PMD block set 41-1 instructs PMD operation calculation to the corresponding HW operation simulation mechanism 50-1 of the PMD (S61), and acquires the PMD operation result from the HW operation simulation mechanism 50-1 of the PMD (S62). The HW operation simulation mechanism 50-1 of the PMD calculates the PMD operation at an input time (input current time) (S61-1), and, after this calculation, instructs ADC conversion start to the HW operation simulation mechanism 50-2 of the ADC, while passing the current time thereto (S61-2). The HW operation simulation mechanism 50-2 of the ADC performs an ADC conversion operation (S61-3).

Subsequently, the model development environment 20 instructs simulation execution to the ADC block set 41-2 (S20-2). In response to the simulation execution instruction, each block in the ADC block set 41-2 instructs ADC operation calculation to the corresponding HW operation simulation mechanism 50-2 of the ADC (S65), and acquires the ADC operation result from the HW operation simulation mechanism 50-2 of the ADC (S66). In response to the ADC operation calculation instruction, the HW operation simulation mechanism 50-2 of the ADC executes ADC operation calculation (S65-1).

Thereafter, the model development environment 20 gives an end instruction, and thereby stops the HW operation simulation mechanism 50-1 of the PMD and the HW operation simulation mechanism 50-2 of the ADC.

In this example, for representing the linkage operation between hardware IPs on the model development environment, the HW operation simulation mechanism of the PMD reads the HW operation simulation mechanism of the ADC in response to an initialization instruction given from the model development environment. Thus, the HW operation simulation mechanism of the PMD can give an instruction to the HW operation simulation mechanism of the ADC without mediation by the model development environment. Upon reception of a call from a PMD block set during simulation execution, the HW operation simulation mechanism of the PMD, which has read the HW operation simulation mechanism of the ADC, instructs conversion operation start to the HW operation simulation mechanism of the ADC in accordance with the switching timing of the PMD output. The HW operation simulations of the ADC and the PMD are directly linked with each other in this way. Therefore, the simulation of the hardware linkage function between the ADC and the PMD is realized without affecting the ADC or PMD block set, and without any operation on the model development environment.

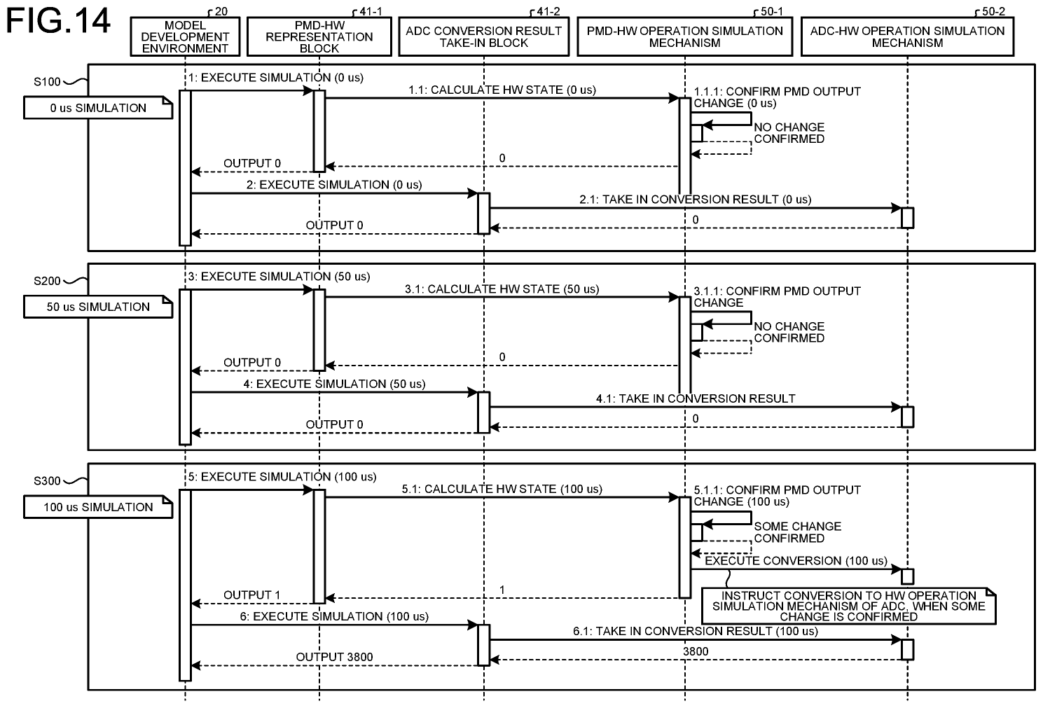

FIG. 14 is a diagram illustrating an example of a detailed sequence until a conversion operation start instruction from the PMD to the ADC at 100 μs, on the assumption that the simulation result of FIG. 13 is obtained by performing a simulation at intervals of 50 μs. In the simulations at 0 μs and 50 μs (S100 to S200), the PMD output does not change. Thus, the HW operation simulation mechanism of the PMD called from the HW representation block of the PMD does not instruct the HW operation simulation mechanism of the ADC, but outputs an initial value of “0”. After the processing of the HW representation block of the PMD, the conversion result acquire block of the ADC acquires a conversion result from the HW operation simulation mechanism of the ADC, but the HW operation simulation mechanism of the ADC returns an initial value of “0” because no conversion operation has been instructed. At 100 μs, since the output of PMD changes, the HW operation simulation mechanism of the PMD called from the HW representation block of the PMD gives a conversion operation start instruction to the HW operation simulation mechanism of the ADC, and returns a changed value of “1”. The HW operation simulation mechanism of the ADC thus instructed converts the input value at this time point, and updates the internal conversion result. Thereafter, the conversion result acquire block of the ADC acquires a conversion result from the HW operation simulation mechanism of the ADC. Since the internal conversion result of the HW operation simulation mechanism of the ADC has been updated, the conversion result acquire block of the ADC acquires an updated value of “3800”, and returns this value to the model development environment.

Advantage of Embodiment

In the related technique, when a hardware IP necessary for embedded system development is handled in a model development environment, some efforts are required, such as use of manual input to perform simulation and code generation. On the other hand, in the design support apparatus according to this embodiment, since a plurality of blocks that represent a hardware IP are included as a block set, it is possible to handle even a non-general-purpose hardware IP in the model development environment. Further, in the design support apparatus according to this embodiment, when a hardware IP block set is used in a model, a simulation is performed by acquiring an operation result of the corresponding hardware for each block included in the block set. Consequently, the simulation and the code generation can be performed without any manual input or with the minimal manual input. Therefore, it is possible to attain an advantage in that the efforts of input operations by users are significantly reduced. Further, it is also possible to attain an advantage in that designing with each company's own hardware IP can be easily performed by utilizing a conventional development environment.

In the conventional technique, there are two problems when each company's own exclusive block is used in a model development environment. The first problem concerns equivalence between a model for simulation and a model for code generation. Since different blocks are used for simulation and code generation, the model for simulation and the model for code generation are different models. In order to confirm matching of the respective models, it is necessity to compare a simulation result of the model for simulation and a code generation result of the model for code generation. The second problem concerns the difference between the block for simulation and the block for code generation in terms of the input/output and the number of blocks used. The block for simulation is a block that includes physical input/output in a state of one-to-one correspondence with hardware parts. On the other hand, the block for code generation is a block that includes logical input/output in a state of one-to-one correspondence with APIs. Since the model for simulation and the model for code generation are different from each other in both of the input/output and the number of blocks used, it is impossible to deal with the models by a simple block replacement.

In the design support apparatus according to the present embodiment, the hardware IP block set is represented by the HW representation block representing the physical input/output as hardware and the SW representation block representing the logical input/output from software to hardware. Consequently, it is also possible to solve the conventional problems.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A computer-implemented design processing method in which a model development environment performs design of a model by a block diagram and simulation of the model, the method comprising:
in response to an initialization instruction from the model development environment, setting individual initial values for operation mechanisms by a block set representing a hardware IP, each of the operation mechanisms performing a hardware operation corresponding to a different one of blocks in the block set;
in response to a simulation execution instruction from the model development environment, giving, by each of the blocks in the block set, an instruction to a corresponding one of the operation mechanisms to execute an operation calculation and acquiring, by each of the blocks in the block set, an operation result from a corresponding one of the operation mechanisms;
acquiring, by the model development environment from the block set, the operation results acquired by the blocks in the block set; and,
in response to an end instruction from the model development environment, giving an instruction to stop operation, the instruction being given by each of the blocks in the block set to a corresponding one of the operation mechanisms.

2. The design processing method according to claim 1, wherein the block set is a set of blocks for representing a hardware IP of an embedded system.

3. The design processing method according to claim 1, further comprising:
reading, by each of the blocks in the block set, mechanism information on a corresponding one of the operation mechanisms; and
setting the initial value for the corresponding operation mechanisms with respect to mechanism information needing an initial value.

4. The design processing method according to claim 1, further comprising executing, in accordance with operation on a UI screen, the design of a model by a general-purpose block provided by the model development environment and the block set.

5. The design processing method according to claim 1, further comprising outputting, by the model development environment, a simulation result based on the operation result.

6. The design processing method according to claim 1, further comprising using, by the model development environment, a general-purpose block provided by the model development environment in combination with the block set.

7. The design processing method according to claim 1, wherein the acquiring of the operation result includes,
in response to a simulation execution instruction from the model development environment, giving an instruction to the operation mechanisms of the hardware IP by operation mechanisms of another hardware IP without mediation by the model development environment, the giving of the instruction being performed by linkage between the operation mechanisms of the hardware IP and the operation mechanisms of the other hardware IP, and
acquiring, by the model development environment, an operation result based on the instruction.

8. The design processing method according to claim 7, further comprising, when the hardware IP and the other hardware IP are provided for an ADC and a PMD,
starting, by the PMD, operation calculation in response to a simulation execution instruction,
giving, to the ADC by the PMD after the operation calculation, an instruction to start conversion, and
performing, by the ADC in response to a simulation start instruction, conversion operation after the conversion.

9. The design processing method according to claim 7, further comprising, when the hardware IP and the other hardware IP are provided for an ADC and a PMD,
activating the ADC at a start of simulation by a conversion start block of the ADC, and
simulating an action that the ADC automatically starts a conversion operation at a timing when output of the PMD is switched by linkage between the ADC and the PMD.

10. The design processing method according to claim 9, further comprising setting an AD conversion timing for the PMD by an AD conversion trigger setting of the PMD.

11. The design processing method according to claim 1, further comprising:
providing the block set with
a block for initial setting where a value of the hardware IP is fixed, and
a block for control where a value of the hardware IP changes during an operation;
performing, by the operation mechanism,
the operation calculation at a time when an instruction from the block for control is given, and
return of a calculated operation result to the block for control; and
acquiring, by the model development environment, the operation result returned to the block for control to obtain a simulation result.

12. The design processing method according to claim 11, further comprising repeating a sequence of:
giving an input value of each time by an HW representation block to the operation mechanism;
keeping, by the operation mechanism, an in-operation state until the input value from the HW representation block reaches a time given by a conversion start block; and,
when the input value from the HW representation block reaches the given time, returning an operation result of the given time by the operation mechanism.

13. The design processing method according to claim 1, further comprising:
providing the block set with
an HW representation block representing physical input/output of hardware, and
an SW representation block representing logical input/output from software to the hardware; and,
in response to a call from the HW representation block and the SW representation block, performing, by the operation mechanism,
an operation of the hardware in accordance with an input of the HW representation block and an input of the SW representation block, and
return of an operation result of the input to the HW representation block and the SW representation block.

14. The design processing method according to claim 13, further comprising:
determining, by the model development environment at a time of code generation of the hardware IP, whether each block in the block set is the SW representation block or the HW representation block; and
performing, by the model development environment, code generation on each block determined as being the SW representation block.

15. The design processing method according to claim 13, further comprising executing the model development environment in an order based on a relation of an input/output connection between SW representation blocks.

16. The design processing method according to claim 14, further comprising:
in response to determining that each block in the block set is the SW representation block, determining, by the model development environment, whether the SW representation block is a block for initial setting or a block for control;
performing, in response to determining to be the code for initial setting, code generation once to generate a code for initialization; and
performing, in response to determining to be the code for control, code generation a plurality of times to generate codes for control.

17. The design processing method according to claim 14, wherein the SW representation block determines a code to be output in accordance with a preset rule for the SW representation block.

18. The design processing method according to claim 14, wherein the SW representation block is differentiated by an APT level

19. The design processing method according to claim 15, further comprising adding input/output for order determination to the SW representation block to indicate the input/output connection relationship between SW representation blocks.

20. The design processing method according to claim 15, further comprising, when there is an order for SW representation blocks,
performing, by the input/output for order determination during simulation, cancelation of a value of an input side and output of an arbitrary value from an output side, and
performing, by the input/output for order determination during code generation, cancelation of code generation.
